(19) United States
(12) Patent Application Publication
(10) Pub. No.: US 2013/0161078 A1
(43) Pub. Date: Jun. 27, 2013

(54) RIGID-FLEX CIRCUIT BOARD AND MANUFACTURING METHOD

(71) Applicant: Hui Hong Jim Kery Li, Singapore (SG)

(72) Inventor: Hui Hong Jim Kery Li, Singapore (SG)

(21) Appl. No.: 13/820,471

(22) PCT Filed: Sep. 3, 2010
(86) PCT No.: PCT/SG10/00322

§ 371 Date: Mar. 1, 2013

(51) Int. Cl. H05K 1/02; H01R 43/16

(52) U.S. Cl. CPC H05K 1/0278; H01R 43/16
USPC 174/254; 29/874

(57) ABSTRACT

Disclosed herein is a cost effective rigid- flex circuit board comprising a flexible section which contents at least one flexible flat cable for interconnect, and a plurality of rigid sections which consists of at least one rigid printed circuit board (8) for components mounting. The improved flexible flat cable comprising at least one layer of flat wires laminated with a plurality of insulating material. The flat wires having non-uniform width and pitch are folded with different angle along the length to resemble wiring patterns of a typical flexible printed circuit board. The rigid section consists of at least one piece of rigid printed circuit board having at least one layer of circuit pattern.

### BACKGROUND OF THE INVENTION

The present invention is related to the field of printed circuit boards, and in particular to the structure and manufacturing method of a cost effective rigid-flex circuit board comprising an improved flexible flat cable and a plurality of rigid printed circuit boards.

Rigid-flex circuit boards and flexible printed circuit boards (FPC) are commonly used as reliable platforms for interconnecting and mounting components on circuits. Particularly, these circuit boards are used in handheld electronic products to alleviate the stringent weight and volumetric requirements. The construction of existing rigid-flex circuit boards is made by combining rigid printed circuit boards and FPCs which primarily utilize polyimide insulating material. Typical applications are found in mobile phones, laptop computers, digital cameras, optical disc drives and MP3 players.

However, there are many problems associated with the structure and fabricating method of existing rigid-flex circuit boards and FPCs such as: a). The complex manufacturing processes of rigid-flex circuit board and FPC affect production yield and require intensive use of acidic chemical to etch away a large portion of copper foils mostly laminated with polyimide insulating film. This etching process produces large amount of toxic waste which is costly to handle during production, storage, transporting, and disposal. b). In an effort to resolve functional design requirements and improve reliability of using rigid-flex circuit board and FPCs, circuit designers tend to minimize mounting components on the flexible section, instead of focusing to assign components on the rigid section or onto the main circuit board. Hence, a large area of the laminated copper sheet is etched and cut away to form the interconnect section, often leaving a relatively small proportion of copper traces supported by stiffener to form the rigid section for component mounting. Thus, this method of making rigid-flex circuit board and FPCs produces large amount of waste material. c). There are also many problems related to the assembly processes of mounting Surface Mount Technology (SMT) components on to rigid-flex circuit board and FPC particularly during solder paste printing process, reflow soldering process and punching process to separate a sheet of circuit consisting several cavities into single circuit board. For examples, (i) during solder paste printing and SMT component mounting, handling of rigid-flex circuit board and FPC circuit boards pose significant difficulties for controlling the circuit board location accurately due to warps, (ii) high temperature reflow oven soldering process often causes adhesive-glued of stiffeners to peel off and also deformation to circuit board affecting dimension tolerance due to shrinkage of polyimide insulating material. These problems are disclosed by present inventor in patent P-No 154201 [WO 2008/105744] for reference.

The foregoing explains the high cost and shortcomings of existing structure and fabrication methods of rigid-flex circuit board and FPC affecting yield resulted from complex production processes, intensive use of etching chemical generating toxic waste which incurs environmental risk, and a large portion of material is etched and cut away to form various circuit board shapes resulting a significant amount of material wasted.

Various structures and methods of fabricating rigid-flex circuit board and FPC have been disclosed. The followings patents are relevant to the invention: U.S. Pat. Nos. 4,800,461; 4,338,149; 4,931,134; 5,004,639; 5,444,188; 5,175,047; 6,099,745; 6,617,519 B2; 6,835,442.

Flexible Flat Cable (FFC) is used for interconnect purpose particularly for linking circuits boards to circuit board. Flexible flat wiring cable is constructed by laminating flatten wires with polyester resin insulating films to form straight copper traces of uniform pitch and width. FFC provides effective, flexibility, foldable, and excellent applications particularly for repetitive bending movements. FFC is relatively lower cost compared to flexible printed circuit board made for interconnect purpose and FFC requires no chemical etching on its production process. Therefore, the use of FFC replacing the interconnecting section of a common rigid-flex circuit board reduces a large amount of etching chemical used. The followings patents on the structure and method of fabricating FFC are relevant to the invention and incorporated here for references: U.S. Pat. Nos. 3,562,036; 3,612,744; 4,375,379; 4,423,282; 6,585,836 B2; 6,954,983 B2; 7,223,919 B2.

However, common FFC having uniform width and pitch of wires traces has constraints to fulfill the vast requirements of wiring trace's size, pitch and wiring patterns for the wiring section of a typical printed circuit board. It is the principal object of this invention to provide a rigid-flex circuit board, relative inexpensive construction and reduced use of etching chemical utilizing an improved flexible flat cable and rigid printed circuit boards. The resulted cost effective rigid-flex circuit board may serve as an alternative choice to circuit board designers.

### SUMMARY OF INVENTION

A cost effective rigid-flex circuit board and its manufacturing method are disclosed with reduced complexity in its configuration and fabrication process. In accordance with the invention, the construction of the rigid-flex circuit board comprises the followings: (a) a flexible wiring interconnect section consist of an improved flexible flat cable; (b) a component mounting section that is realized by the use of rigid printed circuits or flexible printed circuit boards. (c) one end of the flexible flat cable section and the component mounting section are interconnected to form an unitary rigid-flex circuit board. The other end of the flexible cable section is to form open-ended contact terminals, or soldering pads for mounting SMT or through-holes components, or interconnecting another circuit board. The flexible cable section can be slit to various widths having various number of wiring lines and folded to various angles and lengths to reach different distances and directions.

In the disclosed structure and manufacturing process of the rigid-flex circuit board, the most distinctive characteristic of the invention is that an improved flexible flat cable is used for the interconnect section. An object of the invention is to provide a non-uniform pitch and wire conductor width of an improved flexible flat cable to accommodate functional requirements of a typical wiring circuit board. Another object of the invention is to provide an improved flexible flat cable having wiring terminations for soldering through-holes and SMT components. Still another object of the invention is to combine two pieces of flexible flat cables back-to back with adhesive tape and laminate together to form an unitary cable having two-sided contact terminals suitable for pairing with a double sided connector, instead of limiting to the use of a broader single-sided fine-pitch connector.

In accordance with the invention, a manufacturing method of an improved flexible flat cable having non-uniform pitch, non-uniform wire conductor width, and double sided terminals is disclosed. The manufacturing method further comprises the following steps: (1) the wire separating guide-roll of the FFC laminating process is composed with various widths of discs to accommodate non-uniform wire width and pitch customized to specific wire patterns required by wiring interconnect section of a rigid-flex circuit board. Alternatively, a fully customized guide-roll can also be fabricated to have a different pitch and width of flat wire conductors. (2) the laminated wire roll is further added with stiffeners for connecting terminals to one end of the cable (3) the other end of the cable is left uncovered by insulating film for connecting to circuit boards or forming terminals for soldering components. (4) the rolled form of flexible flat cable is then split to form single roll flat cable and further cut to length to form an individual flat cable. (5) the individual flat cable is further slit to separate wire groups. (6) the wire groups are further cut to length, folded to the required angles and terminated with appropriate type of terminals to form an improved flexible flat cable. (7) two pieces of the improved flexible flat cables are back-to-back aligned and laminated to form a double sided terminals type of improved flexible flat cable.

Separately, single layer or multilayer rigid printed circuit boards which assure high mechanical stability are used to form the component mounting section of the rigid-flex printed circuit board.

The improved flexible flat cable is further interconnected to the rigid printed circuit boards to form a rigid-flex circuit board. Interconnecting the flexible flat cable and rigid circuit board can be achieved by direct soldering or inserting the cable terminal to a connector soldered on a circuit board. Alternatively, the flexible flat cable and rigid printed circuit board can be interconnected by utilizing anisotropic conductive film, which typically having lower curing temperature relative to conventional tin based soldering and is suitable for fine-pitch interconnect applications.

This invention thus provides a cost effective rigid-flex circuit board employing an improved flexible flat cable and rigid printed circuit boards, and can advantageously replace the use of relatively expensive conventional rigid-flex circuit boards and FPCs. These and other objects, advantages and features of the present invention will be apparent from the following description of preferred embodiments, considered along with the accompanying drawings.

### BRIEF DESCRIPTION OF THE DRAWINGS

FIG. 1 is a top view of a preferred embodiment fabricated in accordance with present invention;

FIG. 2 is an enlarged view of the embodiment in FIG. 1 illustrating the end section consisting of a rigid printed circuit board mounted with SMT components;

FIG. 3 is an enlarged view of the middle section of the embodiment of FIG. 1, slit to three groups of wire extensions for various length of connections, and having different type of bending angles on the improved flexible flat cable;

FIG. 4-5 is a top view of another preferred embodiment illustrating various folded extensions connected with three rigid printed circuit boards. In particularly, FIG. 5 shows a small rigid printed circuit board is embedded into the center part of the flexible flat cable;

FIG. 6 is an exemplary rigid-flex circuit board having an end section of FIG. 5 interconnecting with a partial view of a larger printed circuit board utilizing anisotropic conductive adhesive;

FIG. 7 is an isometric view of the embodiment described in FIG. 4 and FIG. 8 is another variant of the embodiment;

FIG. 9 is a top view of still another preferred embodiment illustrating the interconnect section having a double-sided flexible flat cable configuration;

FIG. 10 is an enlarged front isometric view of the embodiment described in FIG. 9;

FIG. 11 is an enlarged front section view of the embodiment of FIG. 9 illustrating details of the double sided flexible flat cable interconnecting section;

FIG. 12 is a top view of a preferred embodiment illustrating a wire separating guide-roll assembly incorporated with various sizes of separator discs.

FIG. 13 is an enlarged front section of the guide-roll depicting details of separator discs aligned in a row.

FIG. 14 is a front isometric view of the embodiment described in FIG. 12;

FIG. 15 presents an enlarged isometric view showing details of a separator disc;

### DESCRIPTION OF PREFERRED EMBODIMENTS

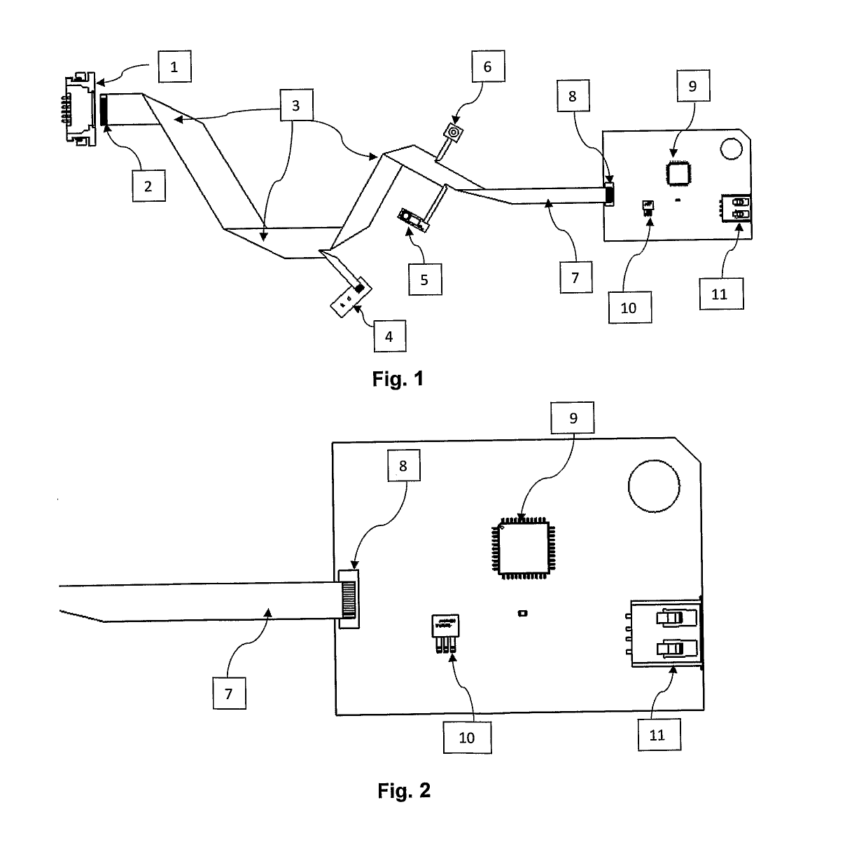

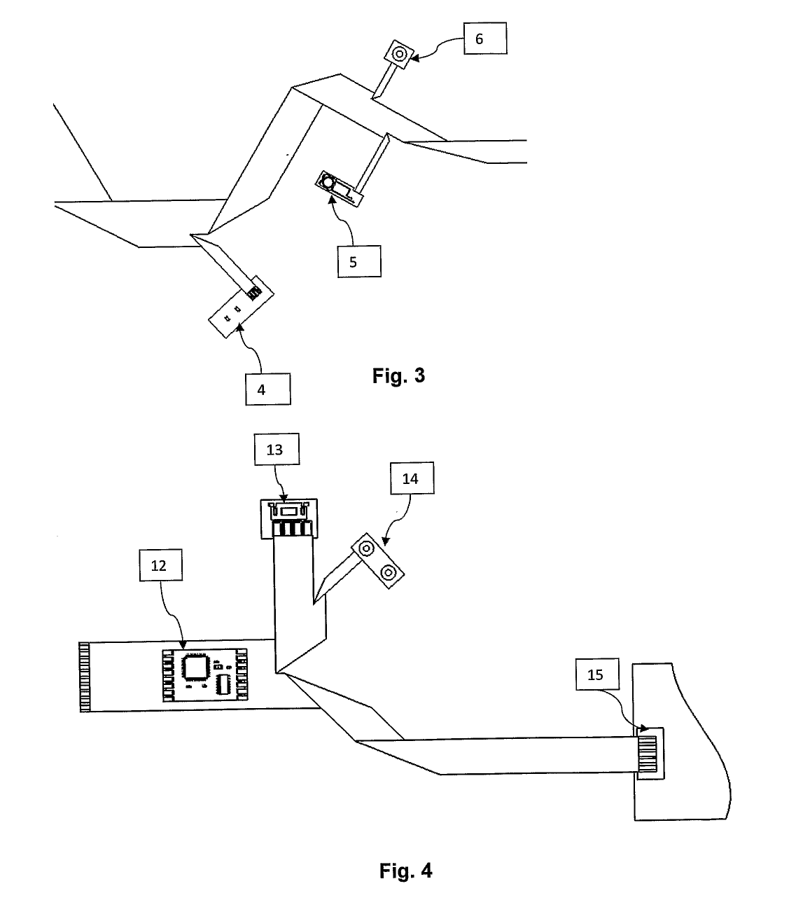

A preferred embodiment for the disclosed rigid-flex circuit board utilizing an improved flexible flat cable showing various extensions for connections and terminated with several circuit boards can best be appreciated by referring to FIGS. 1 to 3. The flexible flat cable end 2 is the contact pads preferably laminated with a layer of stiffener for inserting to connector 1. The flexible flat cable can be folded into different angles 3 customized to each specific application. The cable extension 4 is connected to a small printed circuit board mounted with light emitting diodes. A miniature tact switch is mounted on another group wires extension connected to printed circuit board 5. One extension of the cable is directly soldered to a stamped metal plate 6 for convenient screwed to grounding contact. The other end of the rigid-flex circuit board 7 is connected by soldering to another printed circuit board 8. This circuit board is mounted with a microcontroller 9, a transistor 10 and an USB connector 11.

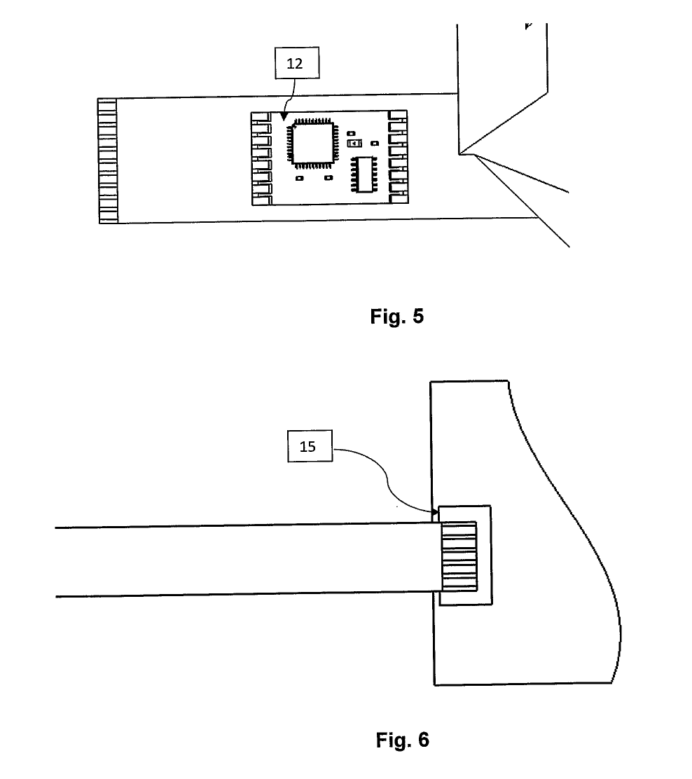

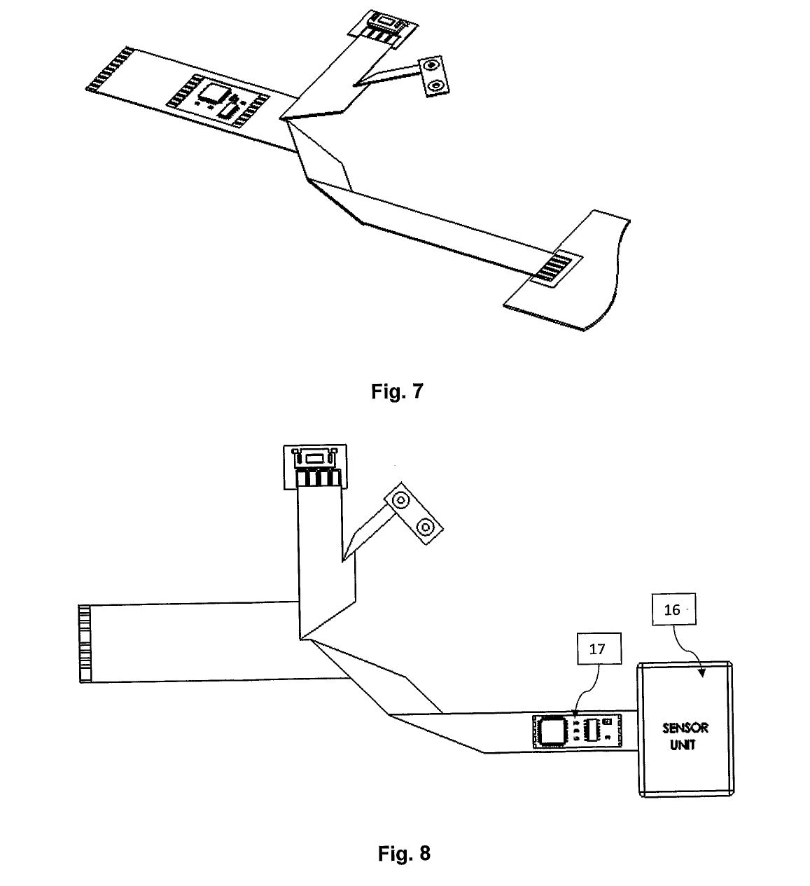

Referring to FIGS. 4 to 7, the inner section of the cable 12 is embedded with a thin rigid printed circuit board mounted with SMT components. One group of wires extension of the rigid-flex circuit board is connected to another printed circuit board mounted with a slide switch 13. Another extension of wire pair is terminated with through-hole pads 14. The other end of the cable 15 is connected to a sensor application board by means of anisotropy conductive film.

FIG. 8 is an exemplary rigid-flex circuit board fabricated in accordance with present invention for sensor applications. Additional aspect and features of present invention may be seen. In particular, a typical sensor application often requires a very weak signal picked up by the sensor unit 16 to be immediately conditioned by a circuitry 17 in proximity to the physical location of the sensor before transmitting the processed signal to the main circuit board. Examples of such sensor unit are capacitive sensors, optical pick-up sensors, magnetic sensors and radio frequency sensors.

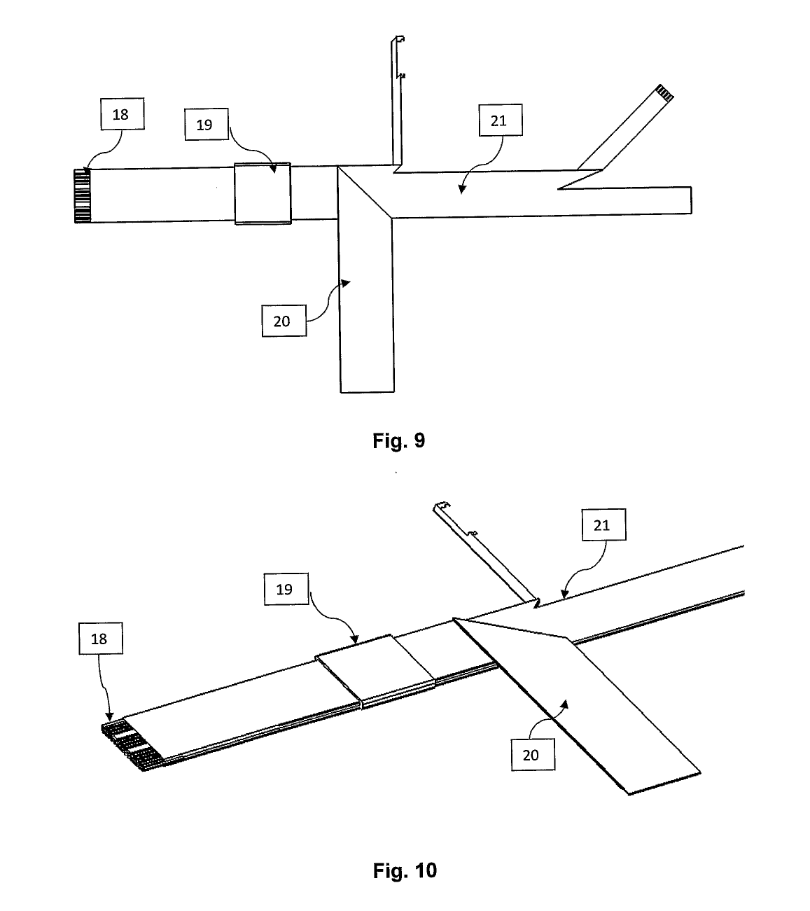

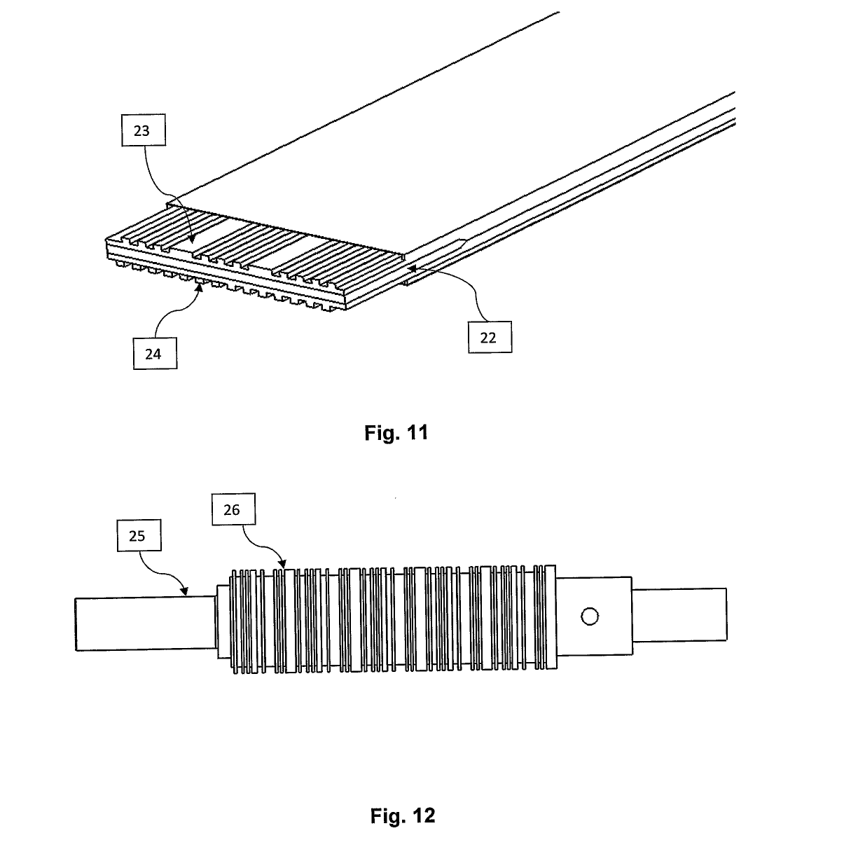

FIGS. 9 to 11 illustrates another preferred embodiment utilizing double-sided flexible flat cable connecting pads 18. The left section of the two flat cables connecting pads, i.e. top cable 20 and bottom cable 21, are laminated in a back-to-back configuration and separated by a thin layer of stiffener 22 to form the overall thickness fit for a double-sided pin connector. A tape holder 17 secured by single-sided adhesive is located at the split junction of two FFC layers to firmly secure the laminated joint. The other section of the rigid-flex circuit board contents a top layer flat cable 18 and a bottom layer 21, which are not laminated together. Each cable is independently slit and folded into different angle along its length customized according to specific applications. FIG. 11 illustrates the detail of non-uniform wire conductors of larger width 23 and smaller width 24 having different pitches.

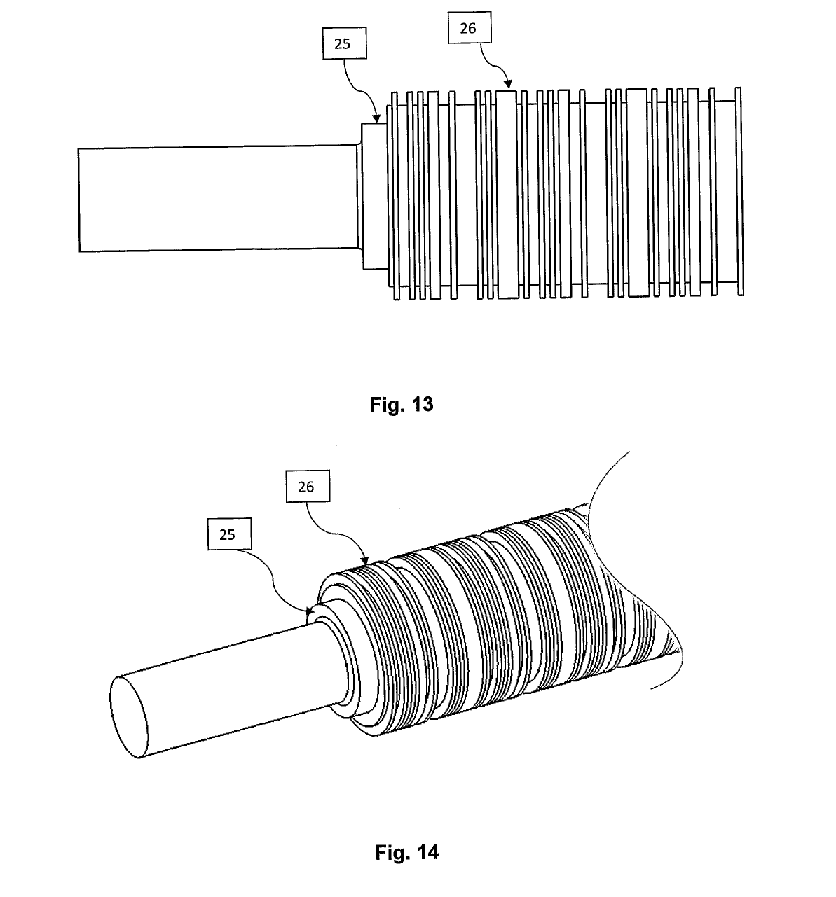

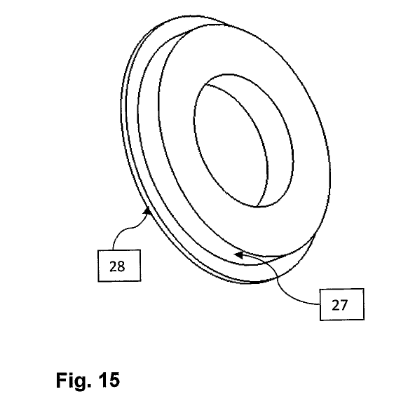

The preferred configuration of the flat wire separating guide-roll assembly in the present invention for fabricating the improved flexible flat cable interconnects section is illustrated in FIGS. 12 to 15. A number of separator discs 26 are assembled into the guide-roll shaft 25 to construct a different pitch 28 separating between wire conductors and accommodating different width 27 of flat wire conductors, to form wiring patterns of the improved flexible flat cable.

As an additional advantage of the present invention, the use of separator discs provide flexibility and choice for the flat cable fabricator to arrange each type of separator disc for constructing wiring patterns.

The preferred embodiments of the invention described herein have been with respect to the use of flexible flat cables as the interconnecting section of the rigid-flex circuit board.

Of particular importance to the present invention is the fact that a variety of flat cable wiring patterns can be constructed using the wire separating guide-roll assembly to resemble various circuit patterns of a typical printed circuit board.

What is claimed is:

1. A cost effective rigid-flex circuit board comprising:
A flexible section for interconnect which consists of at least one improved flexible flat cable, and;
a plurality of rigid sections for component mounting which content of at least one rigid printed circuit board or one flexible printed circuit board.

2. The rigid-flex circuit board according to claim 1, wherein the improved flexible flat cable section consist of non uniform wire conductor pitch. The variable pitch among wire conductors is achieved by changing the guide-roll separator disc spacing mounted on a flexible flat cable laminating apparatus.

3. The rigid-flex circuit board according to claim 1, wherein the improved flexible flat cable section consist of non uniform wire conductor width. The variable width is achieved by utilizing appropriate width of conductors to be placed onto the corresponding guide-roll separator disc spaces on a flexible flat cable laminating apparatus.

4. The rigid-flex circuit board according to claim 1, wherein the improved flexible flat cable section, one terminal end consists of non uniform soldering pad size for soldering through-holes and SMT components. The other terminal end consists of conductor wires laminated with stiffener for inserting into a connector.

5. The rigid-flex circuit board according to claim 1, wherein the improved flexible flat cable section consist of at least one layer wiring conductors.

6. The rigid-flex circuit board according to claim 5, wherein the improved flexible flat cable section is constructed by combining two pieces of flexible flat cables back-to back with adhesive tape and laminated to form an unitary cable having two-sided contact terminals suitable for pairing with a double-sided pins connector.

7. A method of fabricating an improved flexible flat cable for the interconnects section of a rigid-flex circuit board comprising the step of:
Providing a flat wire separating guide-roll assembly containing more than one separator discs having various widths. The first disc is aligned next to the following discs in a row along a shaft;
Both ends of the shaft are housed by bearings. Flat wires having various width and insulation film are fed into a flexible flat cable laminating apparatus to form a flat cable roll;
Selectively bonding the said flat cable ends with different stiffener width and thickness to make connecting terminals. The other end of the cable may form connecting pads;
The said flat cable roll is cut to a required length to form an individual single-sided terminals flat cable and is further slit to separate wire groups. The separated wire groups are folded to required angles and terminated with appropriate type of terminals to produce an improved flexible flat cable;
The said improved flexible flat cable terminal ends can further interconnect with printed circuit boards to form a rigid-flex circuit board.

8. The method of claim 7, further comprising the step of:
Arranging two pieces of the said improved flexible flat cables back-to-back at the single-ended terminal ends to form an improved double-sided flat cable;
The said double-sided flexible flat cable terminal ends can further interconnect with printed circuit boards to form a rigid-flex circuit board
